(19) United States
(12) Patent Application Publication
(10) Pub. No.: US 2005/0024691 A1
(43) Pub. Date: Feb. 3, 2005

(54) Method for fixing a movable module of an electronic apparatus and an electronic apparatus

(76) Inventors: Ming-Kuan Qian, Chiang-Su (CN); Ming-Tsung Cheng, Tao-Yuan Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/709,281

(22) Filed: Apr. 27, 2004

(30) Foreign Application Priority Data
May 9, 2003 (TW) 092112752

(51) Int. Cl. H04N 1/04; H05K 7/00

(52) U.S. Cl. 358/474; 248/687; 248/562; 361/686

(57) ABSTRACT

A method for fixing a movable module of an electronic apparatus is provided, wherein the movable module is installed inside a housing of the electronic apparatus, and the movable module moves when the electronic apparatus is in operation. The method includes providing a fixing member installed on the housing of the electronic apparatus and a positioning member installed on the electronic apparatus, and using a cushion to push the fixing member to the positioning member when the cushion is attached to the housing of the electronic apparatus.

### BACKGROUND OF INVENTION

1. Field of the Invention

The present invention relates to a method for fixing a movable module of an electronic apparatus, and more specifically, to a method for preventing damage due to shaking of the movable module when carrying the electronic apparatus, and an electronic apparatus utilizing the method.

2. Description of the Prior Art

n the latest decade, the development of computer peripherals and other electronic apparatus progresses day by day and they are utilized universally in daily life. Take a scanner as example. A scanner is a very popular electronic apparatus for scanning a document and generating corresponding data, or converting image data, such as photographs, into digital format that can be operated on and modified with a computer. In addition, the scanner may provide some additional functions such as facsimileing image data through a telephone line, or sending image data in e-mail through the Internet, or copying image data as a copy machine, or even posting converted image data on the Internet.

Please refer to FIG. 1 showing an external view of a conventional scanner 10. The scanner 10 includes a housing 12, a transparent platform 14, a track 16, a light source 20, and a scanning module 18. The transparent platform 14 is installed on the housing 12 for placing a document, and the scanning module 18 is installed on the track 16 and can move in either direction along the X axis for scanning the document to generate corresponding image signals. When the scanner 10 scans, the scanning module 18 moves along the track 16 to scan the document, and when the scanning is finished, the scanning module 18 moves back to a specific point A so that the scanner 10 is in idle mode.

As described above, the scanning module is a main device of the scanner. However, in the conventional scanner, a device for fixing the scanning module does not exist. Therefore, when the scanner is in idle mode or not switched on, the scanning module is positioned at the specific point A, but if the scanner is shaken, the scanning module may move to a undesired place due to the absence of fixing devices. Especially when the scanner is carried, for example from a factory to a selling area, the scanner and the scanning module inside could be shaken several times, possibly damaging the scanning module or other devices of the scanner.

Similarly, typical electronic apparatuses include several precision devices that cannot be shocked or shaken. Especially when an electronic apparatus has a movable module like the scanning module mentioned above, the movable module could be damaged, deviate from the normal position, or even collide with other devices. Conventionally when packaging the electronic apparatus, a cushion is attached outside of the housing of the electronic apparatus to prevent damage due to vibration. Although the cushion protects the electronic apparatus from being shaken or shocked, the movable module inside is not protected so that the movable module could slide and collide with other devices, causing damage to the devices inside the electronic apparatus.

### SUMMARY OF INVENTION

It is therefore a primary objective of the present invention to provide a method for fixing a movable module of an electronic apparatus, and an electronic apparatus utilizing the method, to solve the problems mentioned above.

Briefly summarized, a method for fixing a movable module of an electronic apparatus is provided. The movable module is installed inside a housing of the electronic apparatus and the movable module moves when the electronic apparatus is in operation. The method includes providing a fixing member installed on the housing of the electronic apparatus and a positioning member installed on the electronic apparatus, and using a cushion to push the fixing member to the positioning member when the cushion is attached to the housing of the electronic apparatus.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates an external view of a conventional scanner.

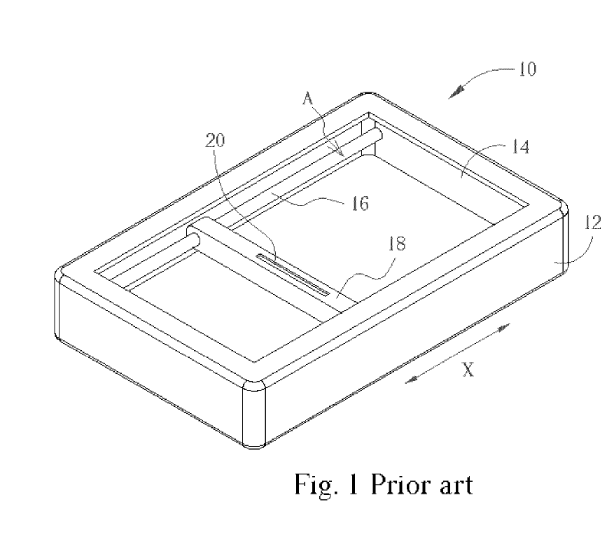

FIG. 2 illustrates an external view of a scanner according to the present invention.

FIG. 3 illustrates a cross-sectional view of the scanner along line C-C″ in FIG. 2.

FIG. 4 illustrates a cross-sectional view of the scanner attached with a cushion along line C-C″ in FIG.2.

FIG. 5 illustrates an external view of a scanner according to a second embodiment of the present invention.

FIG. 6 illustrates a partially enlarged view of a side of the scanner in FIG. 5.

### DETAILED DESCRIPTION

The method according to the present invention can be applied to any kind of electronic apparatus requiring inner part fixation, especially electronic apparatuses with a movable module inside which moves along a direction when operated.

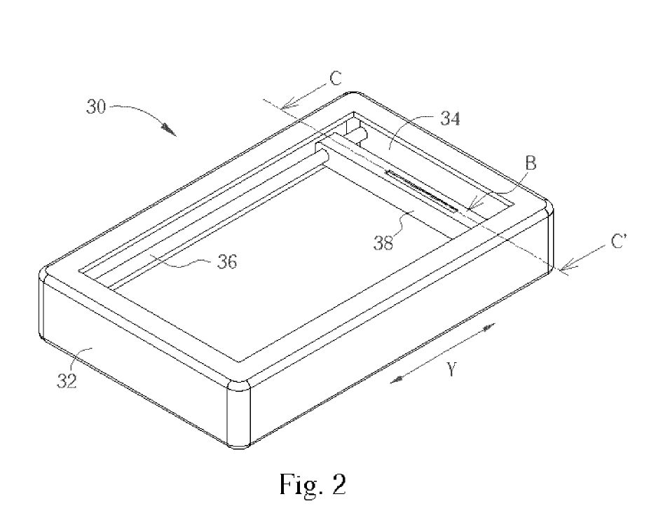

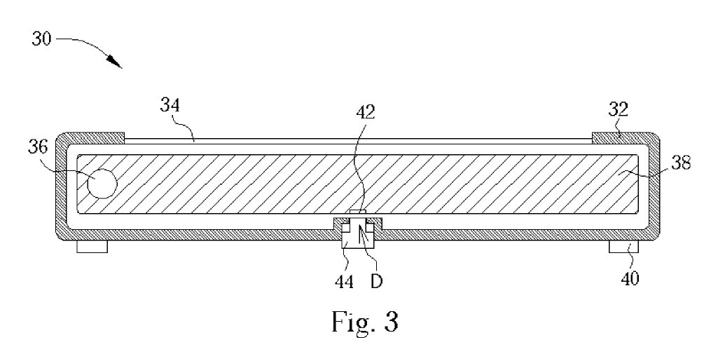

The first embodiment of the present invention is a scanner. Please refer to FIG. 2, showing an external view of a scanner 30 according to the present invention, and FIG. 3, showing a cross-sectional view of the scanner 30 along line C-C″ in FIG. 2. The scanner 30 includes a housing 32, a transparent platform 34, a track 36, a scanning module 38, and four footpads 40. The transparent platform 34 is installed on the housing 32 for placing documents, and the footpads 40, are installed under the housing 32 for stability and support of the scanner 30. The track 36 is installed inside of the housing 32 along a longer side of the housing 32 and the scanning module 38 is installed on the track 36 to be perpendicular to the track 36. When the scanner 30 operates, the scanning module 38 moves along a direction of the Y axis to scan the document. After scanning is finished, the scanning module 38 moves back to point B.

The scanning module 38 further includes a positioning member 42, and a fixing member 44 is installed on a position opposite to the positioning member 42 on the housing 32. As shown in FIG.3, in this embodiment, the positioning member 42 is a recess, and the fixing member 44 is a tip with a protrusion D that can fit in the recess. When the protrusion D fits into the recess, the scanning module 38 can be locked and fixed on point B. The scanner 30 in FIG. 3 is under normal condition or idle mode (not carried). In this situation, the fixing member 44 protrudes from the housing 32 due to its weight, and the protrusion D does not attach the scanning module 38. Under this condition, the fixing member 44 does not interrupt the movement of the scanning module 38.

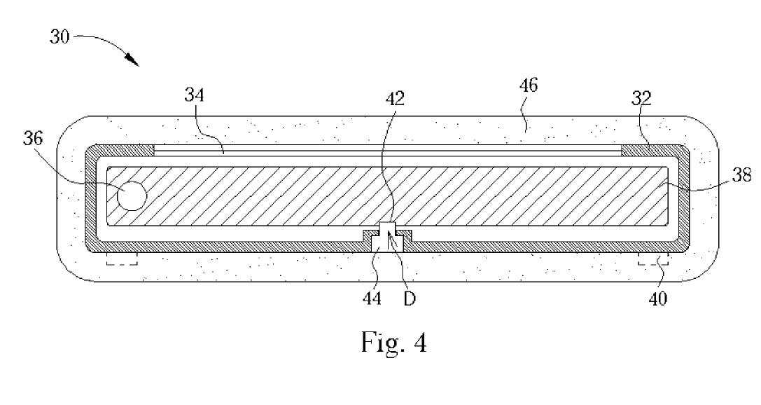

Please refer to FIG.4 showing a cross-sectional view of the scanner 30 attached with a cushion 46 along line C-C″ in FIG.2. When carrying the scanner 30, the cushion 46 is attached to the scanner to prevent vibration and collision. The cushion 46 is generally made of materials such as styrene foam. While being carried, the scanner 30 is not switched on so that the scanning module 38 is located at point B. The position of the fixing member 44 corresponds to the position of the positioning member 42 of the scanning module 38 when stopped at point B as shown in FIG. 4. When the cushion 46 is attached to the scanner 30, the fixing member 44 is pushed by the cushion 46 to move upwards, so that the protrusion D is inserted into the positioning member 42 to lock on the scanning module 38. After the cushion 46 is detached, the fixing member 44 will return to its original position so that the scanning module 38 can operate.

In this embodiment, the fixing member 44 protrudes from the housing 32 under normal condition. In order to ensure the fixing member 44 returns to its original position after the cushion 46 is detached, an elastomer such as a rubber ring or a spring can be installed on the fixing member 44 to pull it to the original position shown in FIG.3 by elasticity. Moreover, the positioning member 42 and the fixing member 44 can be designed in other ways. For example, the positioning member 42 and the fixing member 44 can be hooks to engage each other when the cushion 46 is attached on, in order to lock the scanning module 38.

A typical electronic apparatus has a connecting port for exchanging data with other electronic apparatuses, e.g. a scanner can have USB ports for connecting to other printers or computers. These connecting ports may be installed on the housing of the electronic apparatus without any cover allowing dust to enter the electronic apparatus. The second embodiment of the present invention provides a protection to the connecting port of the electronic apparatus being carried. In this embodiment, a scanner is also used as an example.

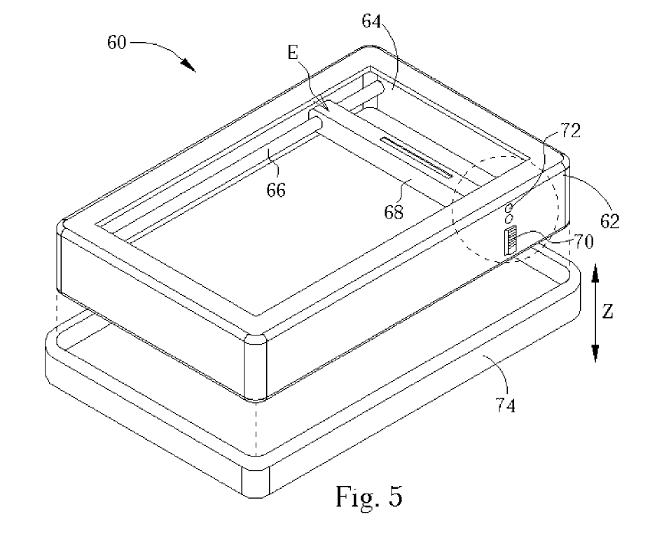

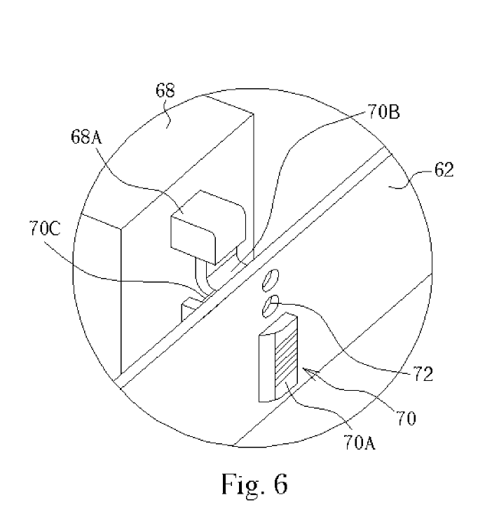

Please refer to FIG. 5 showing an external view of a scanner 60 according to the second embodiment of the present invention, and FIG. 6 showing a partially enlarged view of a side of the scanner 60 in FIG. 5. The scanner 60 includes a housing 62, a transparent platform 64 installed on the housing 62, a track 66 installed inside the housing 62, a scanning module 68 connected to the track 66, a fixing device 70, and a plurality of connecting ports 72 installed alongside of the housing 62. When the scanner 60 operates, the scanning module 68 moves along direction Z, and after scanning is finished, the scanning module 38 moves back to point E. The fixing device 70 is installed on a side of the housing 62 under the connecting ports 72.

As shown in FIG. 6, the fixing device includes a slide bar 70A, a hook 70B, and an elastic device 70C. The slide bar 70A is on the surface of a side of the housing 62, the hook 70B is inside the housing 62 and connected to the elastic device 70C. A fixing device 68A corresponding to the hook 70B is installed on the scanning module 68. When a cushion 74 is attached to the scanner 60 upwards along direction Z in FIG. 5, the cushion 74 pushes the slide bar 70A upwards along direction Z and the hook 70B is moved along with the slide bar 70A toward the fixing device 68A to clip on the fixing device 68A and lock on the scanning module 68. Meanwhile, the slide bar 70A covers the connecting ports 72, protecting the connecting ports 72 from dust. And when the cushion 72 is detached from the scanner 60, the fixing device 70 will be released with help of the elastic device 70C and separated from the fixing device 68A to return to the original position, so that the scanning module 68 can move normally, and the uncovered connecting port 72 is capable of transmitting data.

In contrast to the prior art, the method for fixing a movable module of an electronic apparatus according to the present invention is accompanied with a conventional cushion that can lock on inner devices of the electronic apparatus so that the devices can be protected from deviation or collision due to movement of tthe electronicapparatus. The method according to the present invention does not require any change in the conventional cushion. After the cushion is removed, the movable module will be unlocked. Thus, other designs similar to the present invention for preventing deviation of a movable module also belong to the range of the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A method for fixing a movable module of an electronic apparatus, wherein the movable module is installed inside a housing of the electronic apparatus, and the movable module moves when the electronic apparatus is in operation, the method comprising:
providing a fixing member installed on the housing of the electronic apparatus and a positioning member installed on the electronic apparatus;
using a cushion to push the fixing member to the positioning member when the cushion is attached to the housing of the electronic apparatus.

2. The method of claim 1 further comprising separating the fixing member from the positioning member when the cushion is detached from the housing of the electronic apparatus.

3. The method of claim 2 further comprising providing an elastic device installed on the fixing member so that the fixing member is separated from the positioning member and returns to an original position when the cushion is detached from the housing of the electronic apparatus.

4. The method of claim 2 further comprising providing an elastic device installed on the positioning member so that the positioning member is separated from the fixing member and returns to an original position when the cushion is detached from the housing of the electronic apparatus.

5. The method of claim 1 wherein the fixing member is a protrusion.

6. The method of claim 1 wherein the positioning member is a recess.

7. The method of claim 1 wherein the fixing member includes a hook and the positioning member includes a hook.

8. The method of claim 7 wherein the electronic apparatus further comprises a connecting port installed on the housing of the electronic apparatus, and the fixing member further comprises a slide bar that covers the connecting port when the fixing member clips on the positioning member.

9. The method of claim 1 wherein the electronic apparatus is a scanner and the movable module is a scanning module movable to scan documents when the scanner is in operation.

10. An electronic apparatus implementing the method of claim 1.

11. An electronic apparatus detachably attached to a cushion for protecting the electronic apparatus, the electronic apparatus comprising:
a housing with a fixing device; and
a movable module installed inside the housing with a positioning device to clip on the fixing device,
wherein the fixing device clips on the positioning device by pushing of the cushion, and when the cushion is detached, the fixing device is separated from the positioning device.

12. The electronic apparatus of claim 11 being a scanner.

13. The electronic apparatus of claim 12 wherein the movable module is a scanning module.

14. The electronic apparatus of claim 11 further comprising an elastic device installed on the fixing device to return the fixing device to an original position and separate the fixing device from the positioning device.

15. The electronic apparatus of claim 11 wherein the fixing device is a protrusion.

16. The electronic apparatus of claim 11 wherein the positioning device is a recess.

17. The electronic apparatus of claim 11 wherein the fixing device includes a hook and the positioning member includes a hook.

18. The electronic apparatus of claim 11 wherein the electronic apparatus further comprises a connecting port installed on the housing of the electronic apparatus, and the fixing device further comprises a slide bar that covers the connecting port when the fixing device clips on the positioning device.
